(19) United States
(12) Patent Application Publication
(10) Pub. No.: US 2025/0030383 A1
(43) Pub. Date: Jan. 23, 2025

(54) POWER AMPLIFICATION MODULE

(71) Applicant: Murata Manufacturing Co., Ltd., Kyoto (JP)

(72) Inventors: Satoshi TANAKA, Kyoto (JP); Hideyuki SATO, Kyoto (JP); Yoshiaki SUKEMORI, Kyoto (JP)

(21) Appl. No.: 18/909,281

(22) Filed: Oct. 8, 2024

Related U.S. Application Data
(63) Continuation of application No. PCT/JP2023/014512, filed on Apr. 10, 2023.

(30) Foreign Application Priority Data
Apr. 12, 2022 (JP) 2022-065875

(51) Int. Cl. H03F 1/02; H03F 3/21

(52) U.S. Cl. CPC H03F 1/0288; H03F 3/211; H03F 2200/451

(57) ABSTRACT

A power amplification module includes a carrier amplifier circuit; a carrier bias circuit that supplies a bias to the carrier amplifier circuit; a peak amplifier circuit; and a peak bias circuit that includes a first transistor having a collector or a drain connected to a reference potential and that supplies a bias to the peak amplifier circuit from an emitter or a source of the first transistor. The peak bias circuit is electrically connected to a current output circuit that outputs a predetermined current from the emitter or the source of the first transistor.

### CROSS REFERENCE TO RELATED APPLICATION

This is a continuation of International Application No. PCT/JP2023/014512 filed on Apr. 10, 2023 which claims priority from Japanese Patent Application No. 2022-065875 filed on Apr. 12, 2022. The contents of these applications are incorporated herein by reference in their entireties.

### BACKGROUND ART

### Technical Field

The present disclosure relates to a power amplification module.

The Doherty amplifier circuit is a high-efficiency power amplifier. The Doherty amplifier circuit is configured such that a carrier amplifier that operates without necessarily depending on the power level of an input signal and a peak amplifier that operates in a case where the power level of the input signal is high are connected in parallel. With such a configuration, the Doherty amplifier circuit can improve the efficiency compared to a normal power amplifier.
Patent Document 1: U.S. Patent Application Publication No. 2020/0358405

### BRIEF SUMMARY

The Doherty amplifier circuit described in Patent Document 1 includes a carrier amplifier that operates in Class AB and a peak amplifier that operates in Class C. In the Doherty amplifier circuit, a base bias current lower than the base bias current of the carrier amplifier is supplied to the peak amplifier. In a case where an input signal of the Doherty amplifier circuit is increased, the peak amplifier starts to operate, thereby lowering the load of the carrier amplifier and outputting a large power. In this way, in the Doherty amplifier circuit described in Patent Document 1, the operation is switched depending on the power level of the input signal. Therefore, the gain characteristic and the phase characteristic with respect to the output signal are changed in a case where the peak amplifier starts to operate. For this reason, there is a problem in that the distortion of the output signal is caused, the leakage power to the adjacent channel is increased, or the error vector amplitude is increased. This is caused by the fact that, in a case where the peak amplifier starts to operate, the current flowing to the bias circuit that supplies the bias current to the peak amplifier is small. Therefore, the peak amplifier cannot follow a change in the input signal.

The present disclosure provides a power amplification module including a Doherty amplifier circuit that improves a delay in the response of a bias circuit in a peak amplifier.

A power amplification module according to one aspect of the present disclosure includes a carrier amplifier circuit; a carrier bias circuit that supplies a bias to the carrier amplifier circuit; a peak amplifier circuit; and a peak bias circuit that includes a first transistor having a collector or a drain connected to a reference potential and that supplies a bias to the peak amplifier circuit from an emitter or a source of the first transistor. The peak bias circuit is electrically connected to a current output circuit that outputs a predetermined current from the emitter or the source of the first transistor.

According to the present disclosure, it is possible to provide the power amplification module including the Doherty amplifier circuit that improves a delay in the response of the bias circuit in the peak amplifier.

### BRIEF DESCRIPTION OF THE DRAWINGS

FIG. 1 is a diagram showing an example of the configuration of a power amplification module according to a first embodiment.

FIG. 2 is a diagram showing an example of the configuration of a power amplification module according to a first modification example.

FIG. 3 is a diagram showing an example of the configuration of a power amplification module according to a second modification example.

FIG. 4 is a diagram showing an example of the configuration of a power amplification module according to a third modification example.

FIG. 5 is a diagram showing an example of the configuration of a power amplification module according to a second embodiment.

FIG. 6 is a diagram showing an example of a relationship between a peak amplifier and a current output circuit in a case where a plurality of the peak amplifiers are configured in the power amplification module according to the second embodiment.

FIG. 7 is a diagram showing an example of the configuration of a power amplification module according to a third embodiment.

FIG. 8 is a diagram showing an example of a relationship between a peak amplifier and a current output circuit in a case where a plurality of the peak amplifiers are configured in the power amplification module according to the third embodiment.

FIG. 9 is a diagram showing another example of a relationship between a peak amplifier and a current output circuit in a case where a plurality of the peak amplifiers are configured in the power amplification module according to the third embodiment.

FIG. 10 is a diagram showing an example of the configuration of a power amplification module according to a fourth embodiment.

FIG. 11 is a diagram showing an example of the configuration of a power amplification module according to a fourth modification example.

FIG. 12 is a diagram showing an example of the configuration of a limiter circuit.

FIG. 13 is a diagram showing another example of the configuration of the limiter circuit.

FIG. 14 is a diagram showing an example of the configuration of a power amplification module according to a fifth modification example.

FIG. 15 is a diagram showing an example of the configuration of a power amplification module according to a fifth embodiment.

FIG. 16 is a diagram showing an example of the configuration of a power amplification module according to a sixth modification example.

### DETAILED DESCRIPTION

Hereinafter, embodiments of the present disclosure will be described with reference to drawings. Here, circuit elements having the same reference signs indicate the same circuit elements, and duplicate descriptions thereof will be omitted.

### Power Amplification Module 100 According to First Embodiment

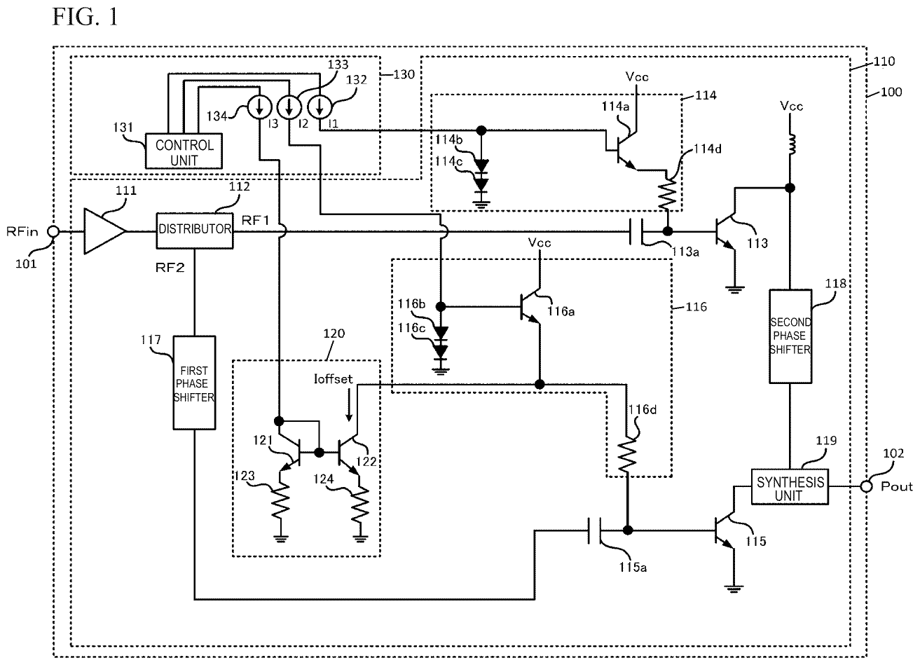

FIG. 1 is a diagram showing a configuration example of various circuits related to a power amplification module 100 according to a first embodiment. The power amplification module 100 is mounted on, for example, a mobile phone and is used to amplify the power of a signal to be transmitted to a base station. The power amplification module 100 can amplify the power of, for example, signals of communication standards, such as a second generation mobile communication system (2G), a third generation mobile communication system (3G), a fourth generation mobile communication system (4G), a fifth generation mobile communication system (5G), long term evolution (LTE)-frequency division duplex (FDD), LTE-time division duplex (TDD), LTE-Advanced, and LTE-Advanced Pro. The communication standards of the signals amplified by the power amplification module 100 are not limited to these.

The power amplification module 100 includes, for example, a power amplifier circuit 110, a current output circuit 120, and a current control circuit 130.

The power amplifier circuit 110 is, for example, a Doherty amplifier circuit. The power amplifier circuit 110 outputs a signal obtained by amplifying an input signal to a predetermined amplitude level. The power amplifier circuit 110 is a circuit that operates in a wide power range by changing a load impedance with the operation of the Doherty amplifier circuit.

The current output circuit 120 is, for example, a circuit that controls a bias circuit of a peak amplifier to cause a certain current to flow to the bias circuit in order to eliminate that the bias circuit of the peak amplifier has a large output impedance in a case where a peak amplifier circuit of the Doherty amplifier circuit operates.

The current control circuit 130 is, for example, a circuit that supplies a certain current to the current output circuit 120.

FIG. 1 illustrates the power amplifier circuit 110 is configured with one carrier amplifier and one peak amplifier, but the present disclosure is not limited to this. The power amplifier circuit 110 may be a power amplifier circuit configured with a plurality of carrier amplifiers and a plurality of peak amplifiers. In this case, the current output circuit 120 may be provided to cause a certain current to flow to the bias circuit of at least any peak amplifier among the plurality of peak amplifiers.

Hereinafter, the configurations of the power amplifier circuit 110, the current output circuit 120, and the current control circuit 130 will be described.

### <<Power Amplifier Circuit 110>>

As shown in FIG. 1, the power amplifier circuit 110 includes, for example, a drive stage amplifier circuit 111, a distributor 112, a carrier amplifier 113, a carrier bias circuit 114, a peak amplifier 115, a peak bias circuit 116, a first phase shifter 117, a second phase shifter 118, and a synthesis unit 119. Each of the constituent elements provided in the power amplifier circuit 110 may be formed on the same substrate or may be formed on a plurality of substrates.

The drive stage amplifier circuit 111 amplifies, for example, an input radio frequency (RF) signal RFin and outputs an amplified signal. The frequency of the signal RFin is, for example, about several GHz. The drive stage amplifier circuit 111 is not particularly limited but is configured with, for example, a bipolar transistor such as a heterojunction bipolar transistor (HBT) or a transistor such as a metal-oxide-semiconductor field effect transistor (MOSFET). The same applies to a transistor that is the carrier amplifier 113 and the peak amplifier 115, which will be described below.

Hereinafter, as an example, a transistor will be described as a bipolar transistor. However, the transistor may be the metal-oxide-semiconductor field effect transistor (MOSFET).

In a case where the transistor is the metal-oxide-semiconductor field effect transistor, in the following, “current” is replaced with “voltage”, “gate” is replaced with “base”, “collector” is replaced with “drain”, and “emitter” is replaced with “source”.

The distributor 112 distributes, for example, the amplified signal output from the drive stage amplifier circuit 111 to a signal RF1 input to the carrier amplifier 113 and a signal RF2 input to the peak amplifier circuit 115. Here, the signal RF2 is a signal delayed by approximately 90 degrees with respect to the phase of the signal RF1 through the first phase shifter 117. Here, it is assumed that the term “approximately 90 degrees delayed” includes those delayed by 45 degrees to 135 degrees. The distributor 112 may be, for example, a distribution constant circuit such as a coupling line 3 dB coupler or a Wilkinson type distributor.

The carrier amplifier 113 amplifies, for example, the signal RF1 input through the capacitor 113a to output an amplified signal. The carrier amplifiers 113 are configured to include, for example, a transistor. In addition, a load (not shown) is connected to a collector of the carrier amplifier 113, and the impedance is R in a case where the peak amplifier 115 does not operate, and the impedance is R/2 in a case where the peak amplifier operates (the peak amplifier is saturated). The carrier amplifier 113 is biased, for example, in Class A, Class AB, or Class B. That is, the carrier amplifier 113 amplifies the input signal RF1 to output an amplified signal without necessarily depending on the power level of the input signal.

The carrier bias circuit 114 is, for example, a circuit that supplies a bias current to a base of the carrier amplifier 113. The carrier bias circuit 114 includes, for example, a transistor 114a, a diode 114b, a diode 114c, and a resistor 114d. The transistor 114a has a collector supplied with a power supply voltage Vcc, a base electrically connected to the current control circuit 130, and an emitter electrically connected to the base of the carrier amplifier 113 through the resistor 114d. The bias current supplied to the base of the carrier amplifier 113 is output from the emitter of the transistor 114a. The diode 114b and the diode 114c are electrically connected in series, an anode of the diode 114b is connected to the base of the transistor 114a, and a cathode of the diode 114c is connected to the ground. The diode 114b and the diode 114c set the base potential of the transistor 114a. The diode 114b and the diode 114c may be a transistor in which a base and a collector are diode-connected.

The peak amplifier 115 amplifies, for example, the signal RF2 input through the capacitor 115a to output an amplified signal. The peak amplifier 115 is configured to include, for example, a transistor. The peak amplifier 115 is biased, for example, in Class C. The peak amplifier 115 may be biased in Class A, Class AB, or Class B.

The peak bias circuit 116 is, for example, a circuit that supplies a bias current to a base of the peak amplifier 115. The peak bias circuit 116 includes, for example, a transistor 116a, a diode 116b, a diode 116c, and a resistor 116d. The transistor 116a has a collector supplied with the power supply voltage Vcc, a base electrically connected to the current control circuit 130, and an emitter electrically connected to the base of the peak amplifier 115 through the resistor 116d. The bias current supplied to the base of the peak amplifier 115 is output from the emitter of the transistor 116a. The diode 116b and the diode 116c are electrically connected in series, an anode of the diode 116b is connected to the base of the transistor 116a, and a cathode of the diode 116c is connected to the ground. The diode 116b and the diode 116c set the base potential of the transistor 116a.

The first phase shifter 117 is connected to, for example, the base of the peak amplifier 115. The first phase shifter 117 is, for example, a ¼ wavelength line.

The second phase shifter 118 is, for example, a ¼ wavelength line that is electrically connected to the collector of the carrier amplifier 113. Accordingly, the high efficiency of the carrier amplifier 113 can be realized by changing the load impedance as viewed from an output end of the carrier amplifier 113.

The synthesis unit 119 synthesizes, for example, the amplified signal output from the carrier amplifier 113 and output through the second phase shifter 118 with the amplified signal output from the peak amplifier 115, to output an output signal Pout to the output terminal 102.

### <<Current Output Circuit 120>>

The current output circuit 120 controls the peak bias circuit 116 such that, for example, a current is caused to flow to the transistor 116a of the peak bias circuit 116 in a case where the peak amplifier 115 does not perform an amplification operation.

The current output circuit 120 includes, for example, a transistor 121, a transistor 122, a resistor 123, and a resistor 124.

The transistor 121 is, for example, a transistor in which a base and a collector are diode-connected. The transistor 121 has, for example, a collector supplied with a reference current I₃ from the current control circuit 130, an emitter electrically connected to the ground (reference potential) through the resistor 123, and a base electrically connected to a base of the transistor 122.

The transistor 122 has a collector electrically connected to the emitter of the transistor 116a of the peak bias circuit 116, a base electrically connected to the base of the transistor 121, and an emitter electrically connected to the ground (reference potential) through the resistor 124.

That is, the current output circuit 120 forms a current mirror circuit with the transistor 121 and the transistor 122. Accordingly, the current output circuit 120 can cause a current I_{offset} to flow to the emitter of the transistor 116a of the peak bias circuit 116 in accordance with the reference current Is supplied from the current control circuit 130 and the ratio between the resistance value of the resistor 123 and the resistance value of the resistor 124. For this reason, the current output circuit 120 can cause a current to flow to the transistor 116a in a case where the peak amplifier 115 does not perform an amplification operation. Accordingly, since the current output circuit 120 can reduce the output impedance of the peak bias circuit 116 before the peak amplifier 115 performs the amplification operation, the delay in the response of the peak bias circuit 116 can be prevented.

It is optional that the current output circuit 120 includes the resistor 123 and the resistor 124. In this case, by adjusting the transistor 121, the transistor 122, and the reference current I₃, a desired current I_{offset} can be caused to flow to the transistor 116a.

### <<Current Control Circuit 130>>

The current control circuit 130 is, for example, a circuit that supplies a reference current, which is a certain current, to the carrier bias circuit 114, the peak bias circuit 116, and the current output circuit 120.

The current control circuit 130 includes, for example, a control unit 131, a first current source 132, a second current source 133, and a third current source 134.

The control unit 131 is, for example, a circuit that controls the currents output from each of the first current source 132, the second current source 133, and the third current source 134.

The first current source 132 is, for example, a current source that supplies a reference current I₁ to the carrier bias circuit 114. The carrier bias circuit 114 supplies a bias current to the carrier amplifier 113 based on the reference current I₁.

The second current source 133 is, for example, a terminal for supplying a reference current I₂ to the peak bias circuit 116. The peak bias circuit 116 supplies a bias current to the peak amplifier 115 based on the reference current I₂.

The third current source 134 is, for example, a terminal for supplying a reference current I₃ to the current output circuit 120.

That is, the current control circuit 130 supplies a certain current according to each of the carrier bias circuit 114, the peak bias circuit 116, and the current output circuit 120. The power amplification module 100 can supply an appropriate current according to each of the carrier bias circuit 114, the peak bias circuit 116, and the current output circuit 120.

### ===Operation of Power Amplification Module 100===

Next, the operation of the power amplification module 100 will be described with reference to FIG. 1. Hereinafter, as an example, the operation of the power amplification module 100 in a case where the input signal RFin at the power level at which the peak amplifier 115 does not operate is input to the power amplification module 100 will be described.

The input signal RFin is input to the drive stage amplifier circuit 111 through an input terminal 101. The drive stage amplifier circuit 111 amplifies the input signal RFin to output an amplified signal. The amplified signal is distributed into the signal RF1 and the signal RF2 by the distributor 112. The signal RF1 is input to the carrier amplifiers 113 through the capacitor 113a. The signal RF2 of which the phase is delayed by 90 degrees by the first phase shifter 117 is input to the peak amplifier 115 through the capacitor 115a.

The carrier bias circuit 114 supplies a bias current for Class A, Class AB, or Class B operation to the carrier amplifier 113 through the resistor 114d. The base bias of the carrier bias circuit 114 is generated by supplying a reference current I₁ to the diode 114b and the diode 114c from the current control circuit 130. That is, since a current flows to the carrier amplifier 113 even in a case where the power level of the input signal RFin is low, the current also flows to the transistor 114a.

The peak bias circuit 116 supplies a bias current for Class C operation to the peak amplifier 115 through the resistor 116d. The base bias of the peak bias circuit 116 is generated by supplying a reference current I₂ to the diode 116b and the diode 116c from the current control circuit 130. That is, since no current flows to the peak amplifier 115 in a case where the power level of the input signal RFin is low, no current flows to the transistor 116a. Accordingly, since the output impedance of the peak bias circuit 116 is high, the time constant is slow, which causes a problem that the envelope of the amplitude of the input signal RFin cannot be followed.

Thus, in the power amplification module 100, the current output circuit 120 is provided to cause a certain current I_{offset} to flow to the transistor 116a of the peak bias circuit 116 without necessarily depending on the power level of the input signal RFin. Specifically, the current output circuit 120 outputs (draws) the certain current I_{offset} from the emitter of the transistor 116a of the peak bias circuit 116 without necessarily depending on the power level of the input signal RFin. That is, with the power amplification module 100 in operation, the transistor 116a is always in an ON state without necessarily depending on the power level of the input signal RFin. In other words, even in a period in which the peak amplifier 115 is not supplied with a current and does not operate, the transistor 116a of the peak bias circuit 116 is supplied with a current. Accordingly, in the power amplification module 100, the output impedance of the peak bias circuit 116 can be reduced even in a case where the peak amplifier 115 starts to operate.

Here, a mechanism for causing the current I_{offset} to flow to the transistor 116a of the peak bias circuit 116 will be described. The current output circuit 120 forms a current mirror circuit. The current output circuit 120 supplies a reference current I₃ to the collector of the transistor 121 from the current control circuit 130. Then, the current output circuit 120 can cause the current I_{offset} according to the ratio of the resistances of the resistor 123 and the resistor 124 to flow to the transistor 116a.

### First Modification Example

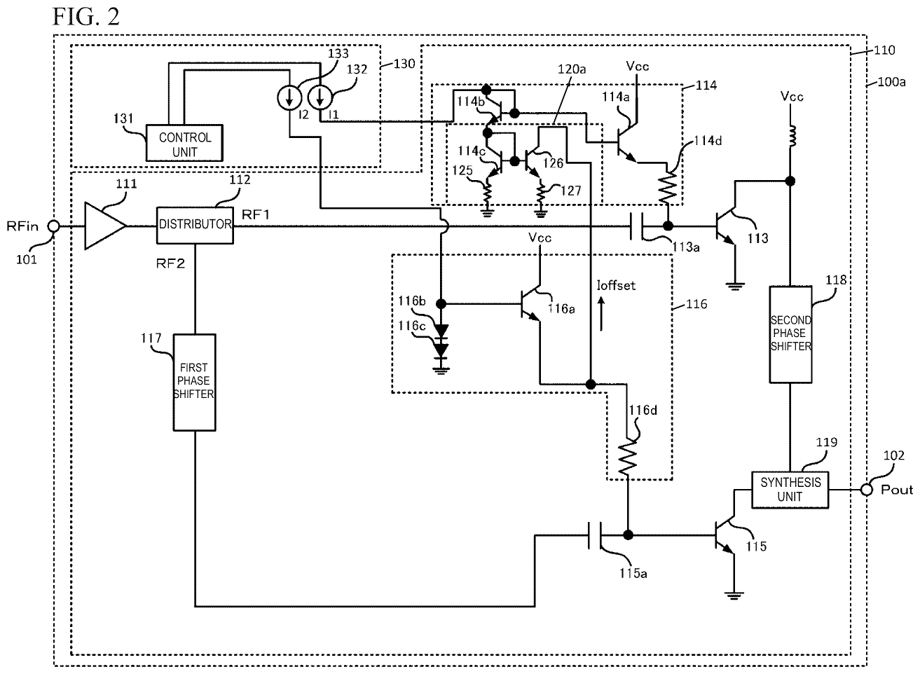

Next, a power amplification module 100a according to a first modification example will be described with reference to FIG. 2. FIG. 2 is a diagram showing an example of the configuration of the power amplification module 100a according to the first modification example. Hereinafter, for convenience, only a configuration different from that of the power amplification module 100 shown in FIG. 1 will be described. In particular, the same operation and effects resulting from the same configuration will not be sequentially referred to.

As shown in FIG. 2, the power amplification module 100a forms a current output circuit 120a by using the diodes of the carrier bias circuit 114, compared to the power amplification module 100. Accordingly, in the power amplification module 100a, the third output terminal 134 for supplying the reference current I₃ to the current output circuit 120 in the power amplification module 100 is unnecessary.

Specifically, the carrier bias circuit 114 includes the diode 114b and the diode 114c in which a collector and a base are diode-connected. In the power amplification module 100a, to form the current output circuit 120a, the emitter of the diode 114c is electrically connected to the ground through the resistor 125, and the transistor 126 is provided. The transistor 126 has a base electrically connected to a base of the diode 114c, a collector electrically connected to the emitter of the transistor 116a, and an emitter electrically connected to the ground through the resistor 127. That is, the transistor 126 forms the diode 114c and the current mirror circuit. Accordingly, in the power amplification module 100a, the transistor 126 can cause the certain current I_{offset} to flow to the transistor 116a without necessarily depending on the power level of the input signal RFin.

In the power amplification module 100a, the third output terminal 134 of the current control circuit 130 in the power amplification module 100 can be reduced by making the reference current I₃ supplied to the current output circuit 120 common with the reference current I₁ supplied to the carrier bias circuit 114. Hence, the power amplification module 100a is configured with a smaller circuit than the power amplification module 100.

### Second Modification Example

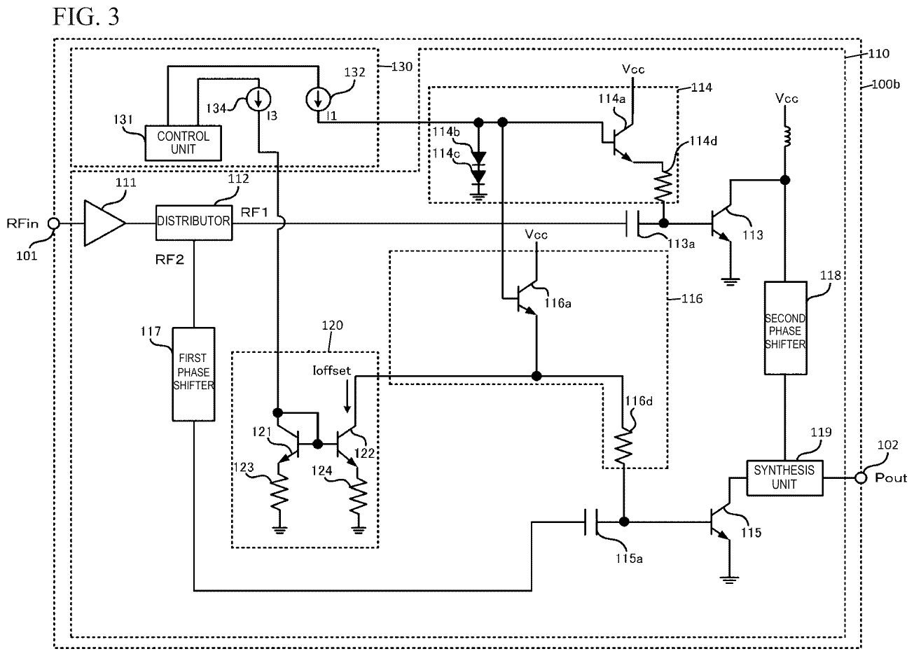

Next, a power amplification module 100b according to a second modification example will be described with reference to FIG. 3. FIG. 3 is a diagram showing an example of the configuration of a power amplification module 100b according to the second modification example. Hereinafter, for convenience, only a configuration different from that of the power amplification module 100 shown in FIG. 1 will be described. In particular, the same operation and effects resulting from the same configuration will not be sequentially referred to.

As shown in FIG. 3, the power amplification module 100b is configured to use the diodes 114b and 114c of the carrier bias circuit 114 to remove the diodes 116b and 116c of the peak bias circuit 116 in the power amplification module 100. Accordingly, it is possible to reduce the number of diodes for the base bias of the peak bias circuit 116, and the second output terminal 133 for supplying the reference current I₂ to the peak bias circuit 116 is unnecessary.

Specifically, the transistor 116a of the peak bias circuit 116 has a base electrically connected to the base of the transistor 114a of the carrier bias circuit 114, a collector supplied with the power supply voltage Vcc, and an emitter electrically connected to the base of the peak amplifier 115 through the resistor 116d. That is, since the peak amplifier 115 has a base potential set by the diodes 114b and 114c, the bias condition for Class C is not established.

Thus, in the power amplification module 100b, the peak amplifier 115 can be operated in Class C by connecting the current output circuit 120 to the emitter of the transistor 116a of the peak bias circuit 116 to draw the current I_{offset} from the emitter of the transistor 116a.

Accordingly, in the power amplification module 100b, the second output terminal 133 of the current control circuit 130 and the diodes 116b and 116c in the power amplification module 100 can be removed while operating the peak amplifier 115 in Class C. Hence, the power amplification module 100b is configured with a smaller circuit than the power amplification module 100.

### Third Modification Example

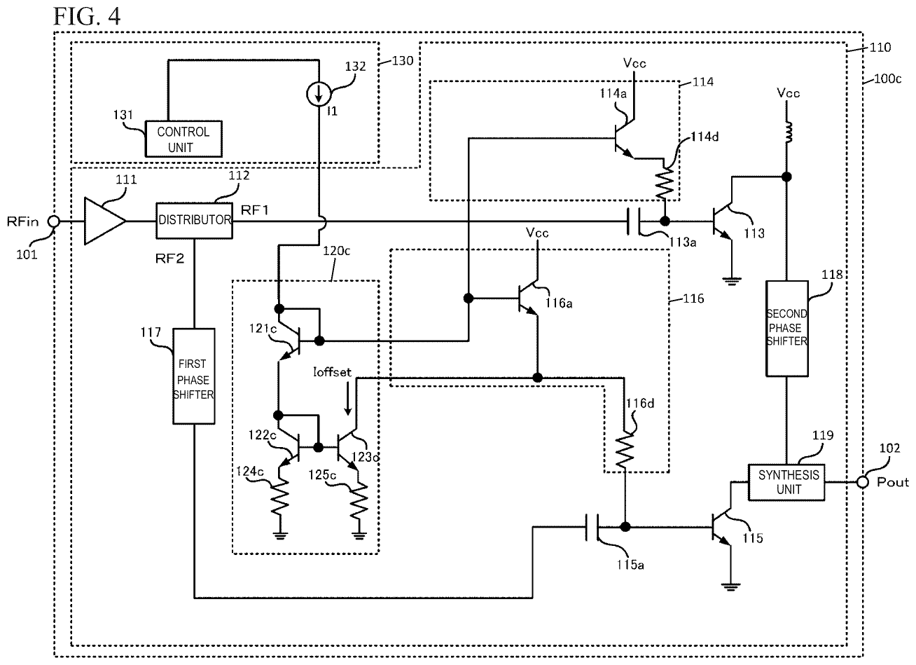

Next, a power amplification module 100c according to a third modification example will be described with reference to FIG. 4. FIG. 4 is a diagram showing an example of the configuration of the power amplification module 100c according to the third modification example. Hereinafter, for convenience, only a configuration different from that of the power amplification module 100 shown in FIG. 1 will be described. In particular, the same operation and effects resulting from the same configuration will not be sequentially referred to.

As shown in FIG. 4, the power amplification module 100c includes a current output circuit 120c in which the current output circuit 120 and the diodes 114b, 114c, 116b, and 116c for setting the base potential of the carrier amplifier 113 and the peak amplifier 115 in the power amplification module 100 are integrated.

The current output circuit 120c controls the peak bias circuit 116 such that a current is caused to flow to the transistor 116a of the peak bias circuit 116, for example, in a case where the peak amplifier 115 does not perform an amplification operation.

The current output circuit 120c includes, for example, a transistor 121c, a transistor 122c, a transistor 123c, a resistor 124c, and a resistor 125c.

The transistor 121c is, for example, a transistor in which a base and a collector are diode-connected. The transistor 121 has, for example, a collector supplied with a reference current I₁ the current control circuit 130, a base electrically connected to the bases of the carrier amplifier 113 and the peak amplifier 115, and an emitter electrically connected to the emitter of the transistor 122c.

The transistor 122c is, for example, a transistor in which a base and a collector are diode-connected. The transistor 122c has an emitter electrically connected to the ground through a resistor 124c, and a base electrically connected to a base of the transistor 123c.

The transistor 123c has a base electrically connected to the base of the transistor 122c, a collector electrically connected to the emitter of the transistor 116a, and an emitter electrically connected to the ground through the resistor 125c.

That is, the current output circuit 120c sets the base potential of the transistor 114a and the transistor 116a by the transistor 121c and the transistor 122c that are diode-connected. In addition, the current output circuit 120c forms a current mirror circuit with the transistor 122c and the transistor 123c. Accordingly, the current output circuit 120c can cause the current I_{offset} to flow to the emitter of the transistor 116a of the peak bias circuit 116 in accordance with the reference current I₁ supplied from the current control circuit 130.

Accordingly, in the power amplification module 100c, the current output circuit 120c is connected to the emitter of the transistor 116a to draw the current I_{offset} to operate the peak amplifier 115 in Class C. In addition, the current output circuit 120c can cause a current to flow to the emitter of the transistor 116a even in a case where the peak amplifier 115 does not perform an amplification operation.

### Power Amplification Module 200 According to Second Embodiment

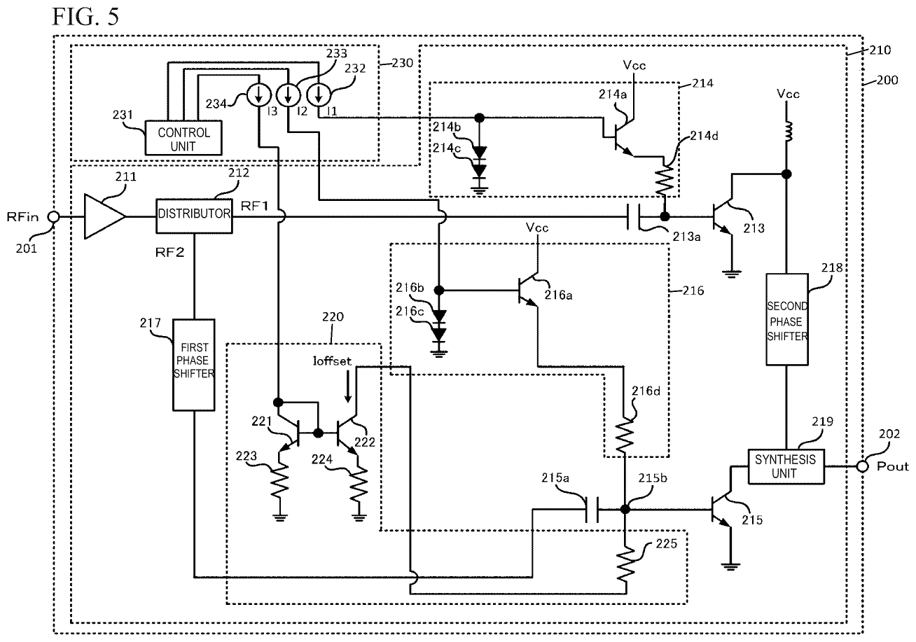

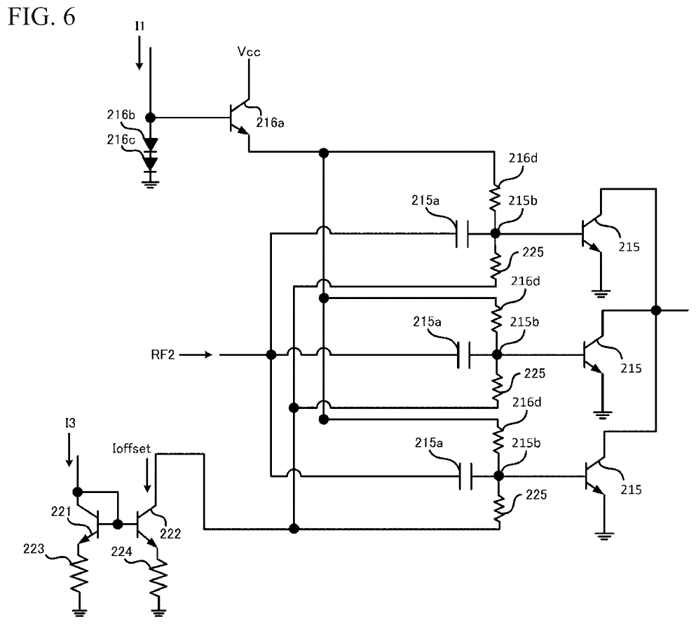

Next, a power amplification module 200 according to a second embodiment will be described with reference to FIGS. 5 and 6. FIG. 5 is a diagram showing an example of the configuration of the power amplification module 200 according to the second embodiment. FIG. 6 is a diagram showing an example of a relationship between a peak amplifier 215 and a current output circuit 220 in a case where a plurality of the peak amplifiers 215 are configured in the power amplification module 200 according to the second embodiment. In the second embodiment, descriptions of the common matters with those of the first embodiment will be omitted, and only differences will be described. In particular, the same operation and effects resulting from the same configuration will not be sequentially referred to.

As shown in FIG. 5, an emitter of a transistor 216a of the peak bias circuit 216 is electrically connected to a base of the peak amplifier 215 through a resistor 216d. It is assumed that one end of the resistor 216d is electrically connected to the emitter of the transistor 216a, and the other end of the resistor 216d is electrically connected to a node 215b electrically connected to the base of the peak amplifier 215.

The current output circuit 220 includes, for example, a transistor 221, a transistor 222, a resistor 223, a resistor 224, and a resistor 225. Since each of the transistor 221, the resistor 223, and the resistor 224 is the same as each of the transistor 121, the resistor 123, and the resistor 124, the descriptions thereof will be omitted.

The transistor 222 has, for example, a collector electrically connected to the node 215b through a resistor 225, a base electrically connected to a base of the transistor 221, and an emitter electrically connected to the ground through a resistor 224. That is, the transistor 222 draws the current I_{offset} from the emitter of the transistor 216a through the resistor 225. In the power amplification module 200, the resistor 225 may be a resistor showing a resistance value close to 0Ω, or it is not necessary that the current output circuit 220 includes the resistor 225.

Next, the operation of the power amplification module 200 will be described. A diode-connected bipolar transistor is turned on at a voltage of about 1.3 V. That is, the base potential of the transistor 216a is about 2.6 V in a case where the reference current I₂ flows. Therefore, the emitter potential of the transistor 216a is about 1.3 V. Then, the peak amplifier 215 is turned on in a case where the input signal RFin is small. Thus, the power amplification module 200 is configured such that the current output circuit 220 draws the current I_{offset} through the resistor 216d connected in series between an emitter of the transistor 216a and a node 215b, in order to appropriately operate the peak amplifier 215. Accordingly, in the power amplification module 200, the peak amplifier 215 can be appropriately operated in Class C by using the voltage drop of the resistor 216d while causing a current to flow to the transistor 216a.

Next, a case where a plurality of the peak amplifiers 215 are configured in the power amplification module 200 will be described with reference to FIG. 6.

As shown in FIG. 6, the power amplification module 200 is configured with the plurality of peak amplifiers 215. The peak amplifiers 215 are not limited to being configured with three amplifiers and may be configured with two or more amplifiers. Each of the plurality of peak amplifiers 215 is electrically connected in parallel. Specifically, each of the plurality of peak amplifiers 215 has a base or a gate and a collector or a drain commonly connected. The input signal RF2 is input to the base of each of the plurality of peak amplifiers 215 through a capacitor 215a. In addition, the emitter of the transistor 216a is electrically connected to the base of each of the plurality of peak amplifiers 215 through the resistor 216d. One end of each of the resistors 216d is electrically connected to the emitter of the transistor 216a, and the other end of each of the resistors 216d is electrically connected to the node 215b electrically connected to the base of each of the peak amplifiers 215.

The collector of the transistor 222 of the current output circuit 220 is electrically connected to each of the nodes 215b through each of the resistors 225. That is, each transistor 222 draws the current I_{offset} from the emitter of the transistor 216a through each of the resistors 216d and each of the resistors 225.

In this way, by configuring the plurality of peak amplifiers 215 and isolation-supplying the base bias from the transistor 216a to each of the plurality of peak amplifiers 215 via an individual resistor 216d interposed therebetween, it is possible to suppress the thermal runaway due to the variation in the current driving capability of the transistors constituting the peak amplifiers. In order to draw the current I_{offset} from the emitter of the transistor 216a while maintaining the effect of suppressing the thermal runaway, in the present embodiment, the current I_{offset} is drawn from the emitter of the transistor 216a through each of the resistors 216d, instead of directly drawing the current I_{offset} from the emitter of the transistor 216a. Moreover, in the power amplification module 200, the current I_{offset} is also drawn from the transistor 222 through the resistor 225 in addition to the resistor 216d. Accordingly, there is an effect of reducing the interference received by the transistor 222 in a case where the RF signal is applied to the base 215b of the transistor 215 via the capacitor 215a.

Accordingly, in the power amplification module 200, a current can always be caused to flow to the transistor 216a of the peak bias circuit 216. Hence, in the power amplification module 200, the output impedance of the peak bias circuit 216 can be kept low even in a case where a current suddenly flows to the transistor of the peak amplifier.

In addition, in the power amplification module 200, a deep Class C bias can be applied to each of the plurality of peak amplifiers 215. Hence, in the power amplification module 200, since the peak amplifiers can be operated only in a case where the input signal is large, the power consumption can be reduced.

### Power Amplification Module According to Third Embodiment

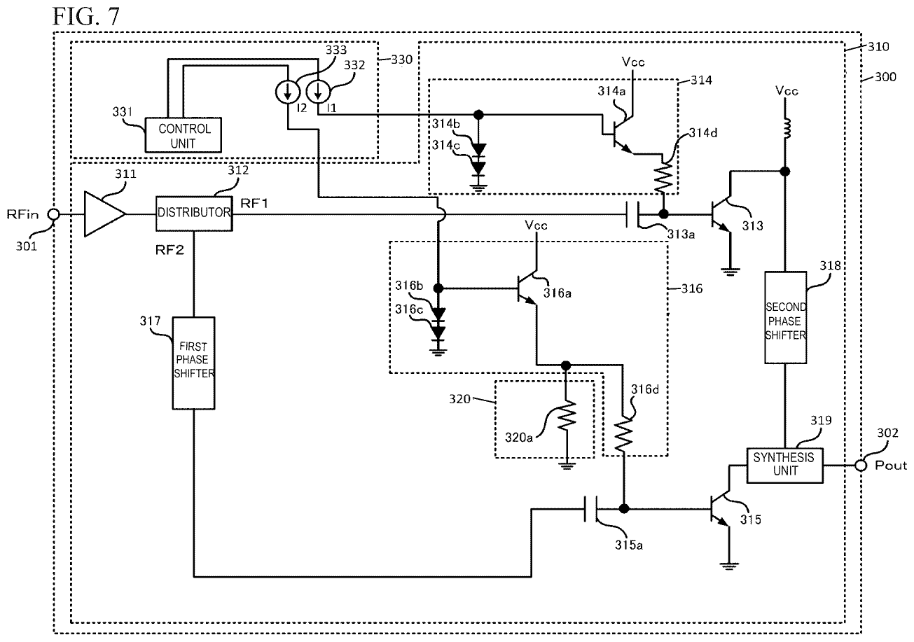

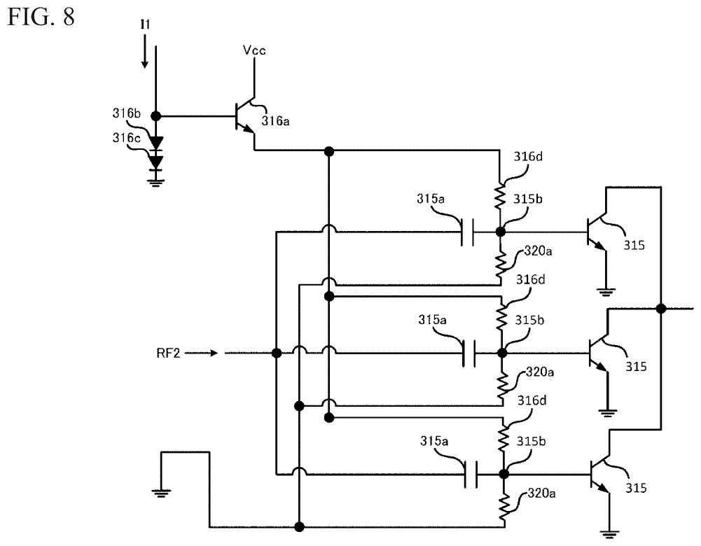

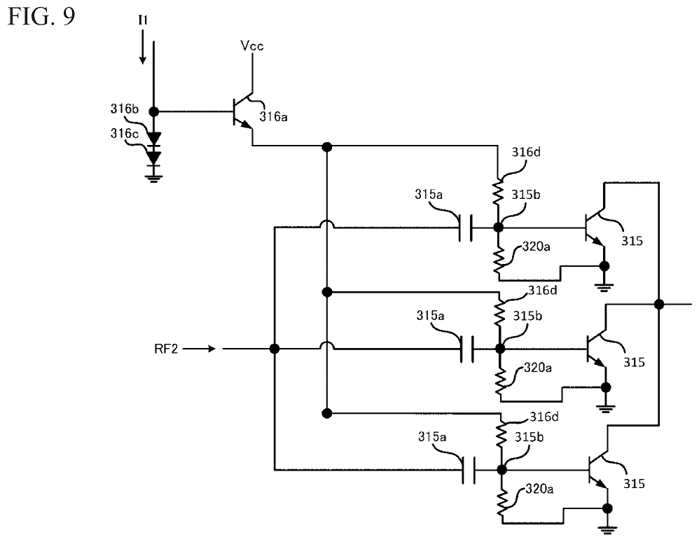

Next, a power amplification module 300 according to a third embodiment will be described with reference to FIGS. 7 to 9. FIG. 7 is a diagram showing an example of the configuration of the power amplification module 300 according to the third embodiment. FIG. 8 is a diagram showing an example of a relationship between a peak amplifier 315 and a current output circuit 320 in a case where a plurality of the peak amplifiers 215 are configured in the power amplification module 300 according to the third embodiment. FIG. 9 is a diagram showing another example of a relationship between the peak amplifier 315 and the current output circuit 320 in a case where the plurality of peak amplifiers 315 are configured in the power amplification module 300 according to the third embodiment. In the third embodiment, descriptions of the common matters with those of the first embodiment will be omitted, and only differences will be described. In particular, the same operation and effects resulting from the same configuration will not be sequentially referred to.

As shown in FIG. 7, the power amplification module 300 is configured such that the current output circuit 320 includes a resistor 320a. One end of the resistor 320a is electrically connected to an emitter of a transistor 316a of a peak bias circuit 316, and the other end thereof is electrically connected to the ground. In the power amplification module 300, the current I_{offset} is drawn from the emitter of the transistor 316a through the resistor 320a. Accordingly, the power amplification module 300 can cause a current to always flow to the transistor 316a of the peak bias circuit 316 by a small number of elements.

Next, an example in which a plurality of the peak amplifiers 315 are configured in the power amplification module 300 will be described with reference to FIG. 8.

As shown in FIG. 8, the power amplification module 300 is configured with the plurality of peak amplifiers 315. The peak amplifiers 315 are not limited to being configured with three amplifiers and may be configured with two or more amplifiers. Each of the plurality of peak amplifiers 315 is electrically connected in parallel. The input signal RF2 is input to the base of each of the plurality of peak amplifiers 315 through a capacitor 315a. In addition, the emitter of the transistor 316a is electrically connected to the base of each of the plurality of peak amplifiers 315 through each of the resistors 316d. One end of each of the resistors 316d is electrically connected to the emitter of the transistor 316a, and the other end of each of the resistors 316d is electrically connected to a node 315b electrically connected to the base of each of the peak amplifiers 315.

One end of each of the resistors 320a1, 320a2, and 320a3 is electrically connected to each of the nodes 315b, and the other end thereof is electrically connected to the ground. That is, each of the plurality of resistors 320a draws the current I_{offset} from the emitter of the transistor 316a.

In this way, by configuring the plurality of peak amplifiers 315 and separately supplying the base bias from the transistor 216a to each of the plurality of peak amplifiers 215 through an individual resistor 216d, it is possible to suppress the thermal runaway due to the variation in the current driving capability of the transistors constituting the peak amplifiers. In order to draw the current I_{offset} from the emitter of the transistor 216a while maintaining the effect of suppressing the thermal runaway, in the present embodiment, the current I_{offset} is drawn from the emitter of the transistor 216a by connecting the resistor 320a constituting the current output circuit to each of the resistors 216d, instead of directly drawing the current I_{offset} from the emitter of the transistor 216a.

Accordingly, in the power amplification module 300, a current can be caused to always flow to the transistor 316a of the peak bias circuit 316. Hence, in the power amplification module 300, the output impedance of the peak bias circuit 316 can be kept low even in a case where a current suddenly flows to the transistor of the peak amplifier.

In addition, in the power amplification module 300, a deep C class bias can be applied to each of the plurality of peak amplifiers 315. Hence, in the power amplification module 300, since the peak amplifier can be operated only in a case where the input signal is large, the power consumption can be reduced.

Next, another example in which a plurality of the peak amplifiers 315 are configured in the power amplification module 300 will be described with reference to FIG. 9. In the following, descriptions of the common matters with those of the embodiment shown in FIG. 8 will be omitted, and only differences will be described. In particular, the same operation and effects resulting from the same configuration will not be sequentially referred to.

As shown in FIG. 9, one end of each of the plurality of resistors 320a is electrically connected to each of the nodes 315b, and the other end thereof is electrically connected to the emitter of each of the peak amplifiers 315. That is, each of the plurality of resistors 320a is electrically connected to the ground common to the emitter of each of the peak amplifiers 315. Accordingly, wiring for connecting each of the plurality of resistors 320a to the ground is facilitated.

### Power Amplification Module According to Fourth Embodiment

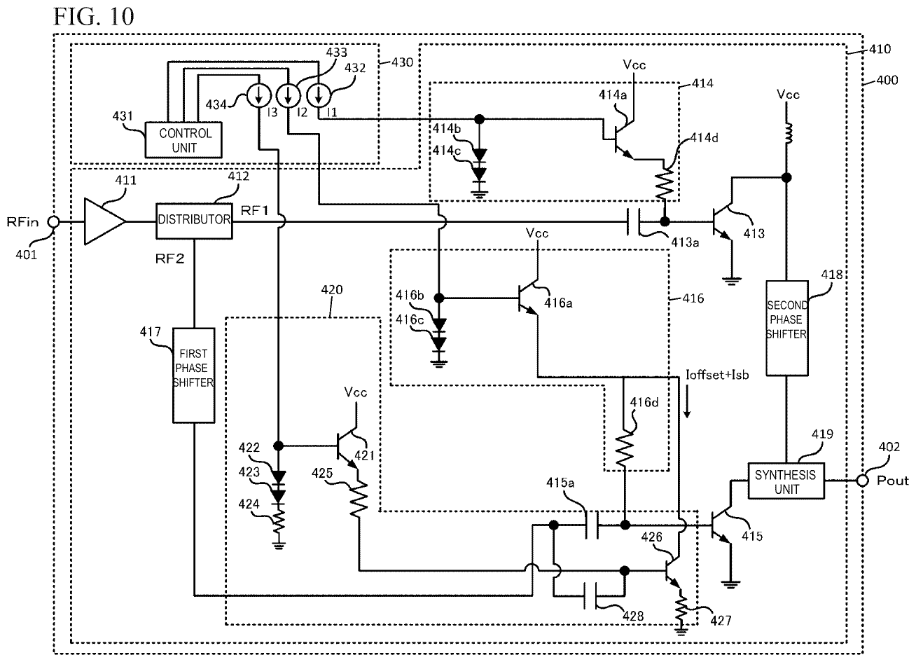

Next, a power amplification module 400 according to a fourth embodiment will be described with reference to FIG. 10. FIG. 10 is a diagram showing an example of the configuration of the power amplification module 400 according to the fourth embodiment. In the fourth embodiment, descriptions of the common matters with those of the first embodiment will be omitted, and only differences will be described. In particular, the same operation and effects resulting from the same configuration will not be sequentially referred to.

As shown in FIG. 10, a current output circuit 420 of the power amplification module 400 includes, for example, a transistor 421, a diode 422, a diode 423, a resistor 424, a resistor 425, a transistor 426, and a resistor 427.

The transistor 421 has a base electrically connected to the current control circuit 430, a collector supplied with the power supply voltage Vcc, and an emitter electrically connected to a base of the transistor 426 through the resistor 425. A reference current I₃ is supplied from a third output terminal 433 of the current control circuit 430 to a base of the transistor 421. One end of each of the diode 422, the diode 423, and the resistor 424, which are electrically connected in series, is electrically connected to the base of the transistor 421, and the other end thereof is electrically connected to the ground. The base potential of the transistor 421 is set by the diode 422, the diode 423, and the resistor 424.

The transistor 426 has a base electrically connected to the emitter of the transistor 421, a collector electrically connected to an emitter of a transistor 416a of a peak bias circuit 416, and an emitter electrically connected to the ground through the resistor 427. In addition, the input signal RF2 is input to the base of the transistor 426 through a capacitor 428.

Next, the operation of the power amplification module 400 will be described. In the power amplification module 400, the current I_{offset} is caused to flow from the emitter of the transistor 416a to the collector of the transistor 426 in accordance with the reference current I₃ input to the base of the transistor 421. Moreover, in the power amplification module 400, a current I_{SB} that is a self-bias current is caused to flow from the emitter of the transistor 416a to the collector of the transistor 426 in accordance with the input signal RF2 input to the base of the transistor 426. That is, in the power amplification module 400, since the current I_{SB} is increased in a case where the power level of the input signal RF2 is increased, it is possible to suppress the operation of a peak amplifier 415 in the low input signal RF2.

Here, the current I_{SB} is adjusted by the capacitance value of the capacitor 428 and the resistance value of the resistor 427. That is, the current output circuit 420 adds the current I_{SB} flowing by the self-bias effect to the current I_{offset} in a case where the power level of the input signal RF2 is increased by inputting the input signal RF2 input to the peak amplifier 415 to the transistor 426.

### Fourth Modification Example

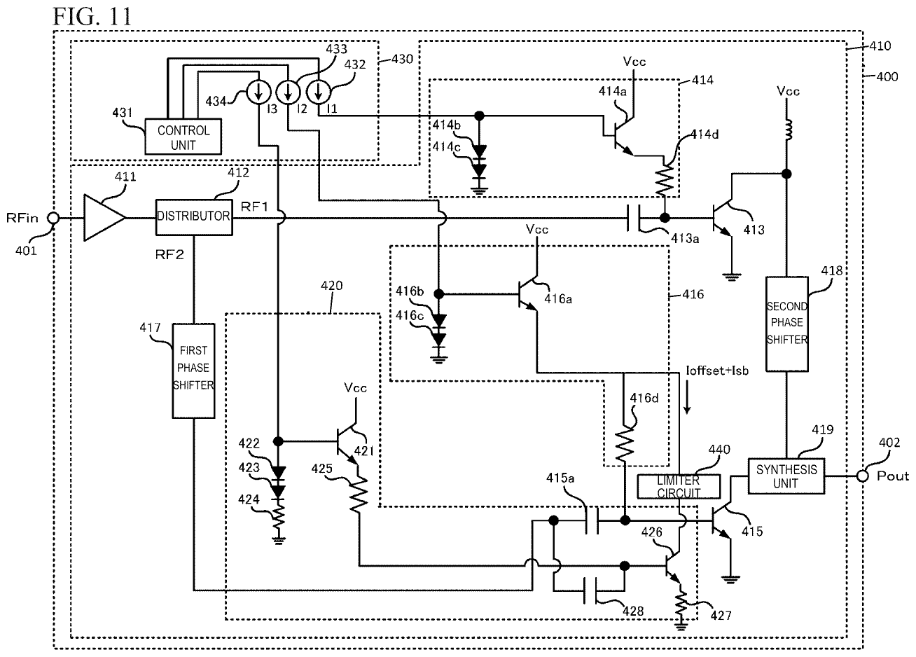

Next, a power amplification module 400a according to a fourth modification example will be described with reference to FIG. 11. FIG. 11 is a diagram showing an example of the configuration of the power amplification module 400a according to the fourth modification example. In the fourth modification example, descriptions of the common matters with those of the power amplification module 400 shown in FIG. 10 will be omitted, and only differences will be described. In particular, the same operation and effects resulting from the same configuration will not be sequentially referred to.

As shown in FIG. 11, the power amplification module 400a includes a limiter circuit 440. The limiter circuit 440 is, for example, a circuit that controls a sum of the current I_{offset} and the current I_{SB} flowing to the collector of the transistor 426 not to exceed a predetermined current value. The limiter circuit 440 is electrically connected in series, for example, between the emitter of the transistor 416a and the collector of the transistor 426.

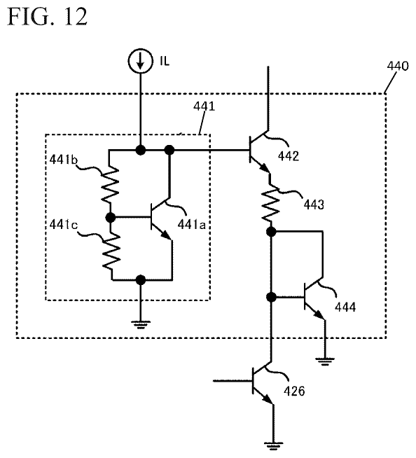

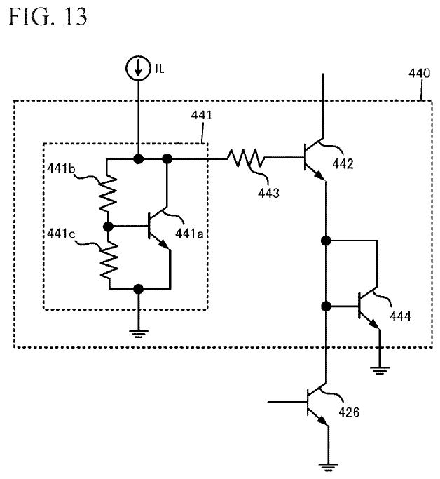

An example of the configuration of the limiter circuit 440 will be described with reference to FIGS. 12 and 13. FIG. 12 is a diagram showing an example of the configuration of the limiter circuit 440. FIG. 13 is a diagram showing another example of the configuration of the limiter circuit 440.

As shown in FIG. 12, the limiter circuit 440 includes, for example, a reference voltage circuit 441, a transistor 442, a resistor 443, and a transistor 444. It is not necessary that the limiter circuit 440 includes the transistor 444.

The reference voltage circuit 441 includes, for example, a transistor 441a, a resistor 441b, and a resistor 441c. A reference current IL is input to the collector of a transistor 441a and is electrically connected to a base of the transistor 442. An emitter of the transistor 441a is electrically connected to the ground. The resistor 441b electrically connects a base and the collector of the transistor 441a. The resistor 441c electrically connects the base and the emitter of the transistor 441a. That is, the reference voltage circuit 441 generates a voltage αV_{be}, which is α times a base-emitter voltage V_{be} of the transistor 441a, at a collector of the transistor 442. The “α times” is a multiple obtained by dividing the sum of the resistance value of the resistor 442b and the resistance value of the resistor 442c by the resistance value of the resistor 442c.

The transistor 442 has a collector electrically connected to the emitter of the transistor 416a, and an emitter electrically connected to the collector of the transistor 426 through the resistor 443. The potential of the emitter of the transistor 442 is (α−1)V_{be}. The transistor 444 has a collector and a base electrically connected to the emitter of the transistor 442, and an emitter electrically connected to the ground.

That is, in the limiter circuit 440, in a case where the collector current of the transistor 426 is increased, the voltage drop of the resistor 443 is increased. In this case, the potential of the collector of the transistor 426 is lowered. For this reason, an increase in current flowing to the collector of the transistor 442 is suppressed. Here, the transistor 444 operates as a protection circuit in a case where the power level of the input signal RF2 is increased.

In the above description, the limiter circuit 440 is described as a circuit different from the current output circuit 420. However, for convenience, the limiter circuit 440 is merely described as being a circuit different from the current output circuit 420, and the present disclosure is not limited to this. For example, the current output circuit 420 may be an integrated circuit including the limiter circuit 440.

Next, a limiter circuit in which a connection position of the resistor 443 in the limiter circuit 440 shown in FIG. 12 is different will be described with reference to FIG. 13. As shown in FIG. 13, in the limiter circuit 440, the resistor 443 is electrically connected in series between the reference voltage circuit 441 and the base of the transistor 442, instead of being electrically connected in series between the emitter of the transistor 442 and the collector of the transistor 426. In this case, in a case where the collector current of the transistor 426 is increased, the base current of the transistor 442 is also increased. In this case, a potential difference occurs between both ends of the resistor 443. Then, the potential of the emitter of the transistor 442 is lowered, and the potential of the collector of the transistor 426 is lowered. Accordingly, an increase in the current flowing to the collector of the transistor 442 is suppressed.

### Fifth Modification Example

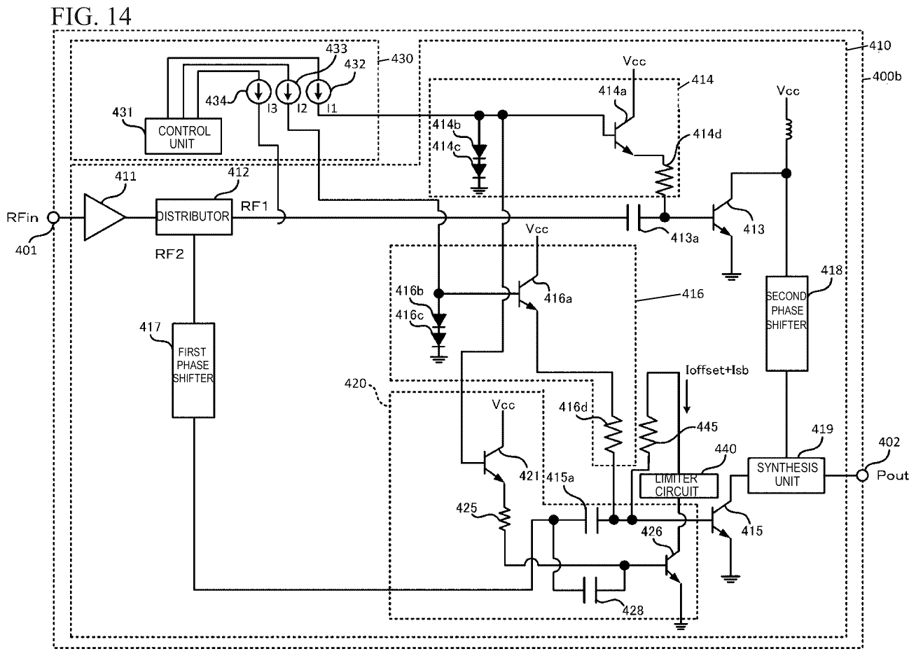

Next, a power amplification module 400b according to a fifth modification example will be described with reference to FIG. 14. FIG. 14 is a diagram showing an example of the configuration of the power amplification module 400b according to the fifth modification example. In the fifth modification example, descriptions of the common matters with those of the power amplification module 400a according to the fourth modification example shown in FIG. 11 will be omitted, and only differences will be described. In particular, the same operation and effects resulting from the same configuration will not be sequentially referred to.

As shown in FIG. 14, the power amplification module 400b is configured to use a diode of the carrier bias circuit 414 compared to the power amplification module 400a. Accordingly, the number of diodes can be reduced, and the third output terminal 433 for supplying the reference current I₃ to the current output circuit 420 is unnecessary.

Specifically, the transistor 421 of the current output circuit 420 has a base electrically connected to a base of a transistor 414a of the carrier bias circuit 414, a collector connected to the power supply voltage Vcc, and an emitter electrically connected to the base of the transistor 426 through the resistor 425. That is, since the transistor 421 has a base potential set by the diodes 414b and 414c, the transistor 421 operates under the same bias condition as the carrier bias circuit 414.

In addition, in the power amplification module 400b, the transistor 426 has an emitter electrically connected to the ground directly. In addition, the limiter circuit 440 is provided such that, for example, the collector of the transistor 426 is electrically connected to a base of the peak amplifier 415 through a resistor 445, and the emitter of the transistor 416a is electrically connected to the collector of the transistor 426 indirectly through the resistor 445. In this way, the limiter circuit 440 can also be applied to a case where the current I_{offset} is drawn from the emitter of the transistor 416a shown in the power amplification module 200 according to the second embodiment via a ballast resistor. In this case, since the deep Class C bias can be applied to the peak amplifier 415, the peak amplifier 415 can be completely turned off to reduce the power consumption.

### Power Amplification Module 500 According to Fifth Embodiment

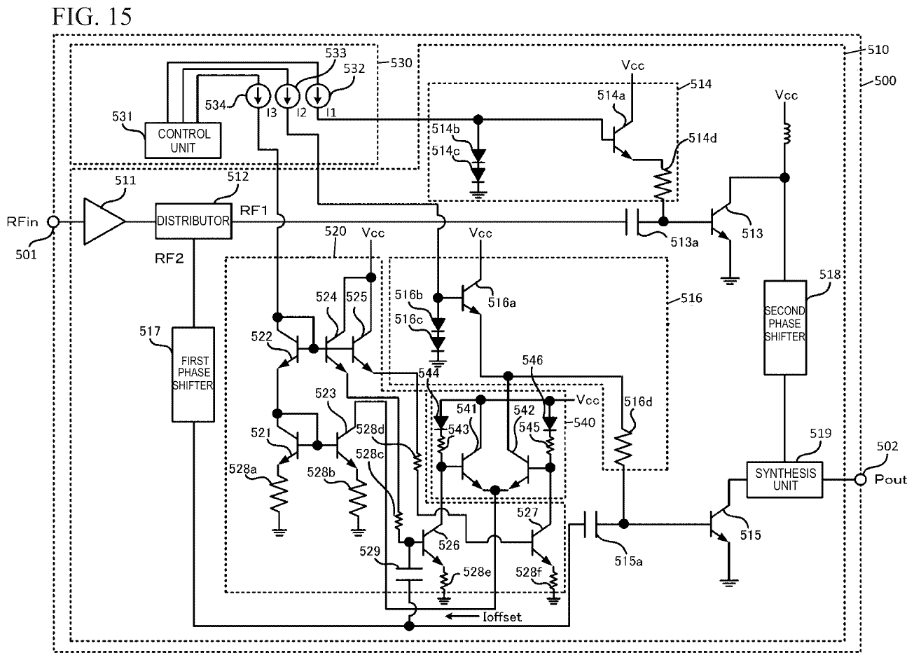

Next, a power amplification module 500 according to a fifth embodiment will be described with reference to FIG. 15. FIG. 15 is a diagram showing an example of the configuration of the power amplification module 500 according to the fifth embodiment. In the fifth embodiment, descriptions of the common matters with those of the power amplification module 100 shown in FIG. 1 will be omitted, and only differences will be described. In particular, the same operation and effects resulting from the same configuration will not be sequentially referred to.

As shown in FIG. 15, the power amplification module 500 includes, for example, a current output circuit 520 and a limiter circuit 540.

The current output circuit 520 includes, for example, transistors 521 to 527, resistors 528a to 528e, and a capacitor 529.

The transistor 521 is, for example, a transistor in which a base and a collector are diode-connected. The transistor 521 has, for example, a collector electrically connected to an emitter of the transistor 522, an emitter electrically connected to the ground through a resistor 528a, and a base electrically connected to a base of the transistor 523.

The transistor 522 is, for example, a transistor in which a base and a collector are diode-connected. The transistor 522 has, for example, a collector electrically connected to the third output terminal 534 of the current control circuit 530, an emitter electrically connected to the collector of the transistor 521, and a base electrically connected to a base of a transistor 524 and a base of a transistor 525.

The transistor 523 has, for example, a collector electrically connected to the limiter circuit 540 to be supplied with the current I_{offset}, an emitter electrically connected to the ground through a resistor 528b, and a base electrically connected to the base of the transistor 521.

The transistor 524 has, for example, a collector supplied with the power supply voltage Vcc, an emitter electrically connected to a base of a transistor 526 through a resistor 528c, and a base electrically connected to the base of the transistor 522.

The transistor 525 has, for example, a collector supplied with the power supply voltage Vcc, an emitter electrically connected to a base of the transistor 527 through a resistor 528d, and a base electrically connected to the base of the transistor 522.

The transistor 526 has, for example, a collector electrically connected to the limiter circuit 540, an emitter electrically connected to the ground (reference potential) through the resistor 528e, and a base electrically connected to the emitter of the transistor 524 through the resistor 528c. The input signal RF2 is input to the base of the transistor 526 through a capacitor 529.

The transistor 527 has, for example, a collector electrically connected to the limiter circuit 540, an emitter electrically connected to the ground through a resistor 528f, and a base electrically connected to the emitter of the transistor 525 through the resistor 528d.

The limiter circuit 540 includes, for example, transistors 541 and 542, resistors 543 and 545, and diodes 544 and 546. The diodes 544 and 546 may be transistors in which a base and a collector are diode-connected.

The transistor 541 has a collector supplied with the power supply voltage Vcc, an emitter electrically connected to the collector of the transistor 523, and a base electrically connected to the collector of the transistor 526. In addition, an emitter of the transistor 541 is electrically connected to the emitter of the transistor 542. In addition, the transistor 541 has a collector electrically connected to an anode of the diode 544, and a base electrically connected to a cathode of the diode 544 through the resistor 543.

The transistor 542 has a collector electrically connected to an emitter of a transistor 516a, an emitter electrically connected to the collector of the transistor 523, and a base electrically connected to the collector of the transistor 527. In addition, the emitter of the transistor 542 is electrically connected to the emitter of the transistor 541. In addition, the base of the transistor 542 is electrically connected to a cathode of the diode 546 through the resistor 545. The power supply voltage Vcc is supplied to an anode of the diode 546.

That is, the limiter circuit 540 is a differential pair of circuits formed of the transistor 541 and the transistor 542.

It is not necessary that the limiter circuit 540 includes the diode 544 and the diode 546.

Next, the operation of the power amplification module 500 will be described.

In the power amplification module 500, the input signal RF2 is input to the base of the transistor 526 through the capacitor 529. A bias is supplied to the base of the transistor 526 through the transistor 524 and the resistor 528c. A bias is supplied to the base of the transistor 527 through the transistor 525 and the resistor 528d. The base potential of the transistor 541 of the limiter circuit 540 is determined by the collector current of the transistor 526 and the characteristics of the resistor 543 and the diode 544. The base potential of the transistor 542 of the limiter circuit 540 is determined by the collector current of the transistor 527 and the characteristics of the resistor 545 and the diode 546.

Here, the operation of the current output circuit 520 and the limiter circuit 540 in a situation where the peak amplifier 515 does not operate will be described. In a case where a current flowing to the transistor 526 is the same as a current flowing to the transistor 527, and the impedance of the resistor 543 and the diode 544 and the impedance of the resistor 545 and the diode 546 are the same impedance, the base potential of the transistor 541 is equal to the base potential of the transistor 542.

Then, a current that is half of the current I_{offset} flowing to the collector of the transistor 523 flows to the emitter of the transistor 516a.

Then, as the power level of the input signal RF2 increases, the current flowing to the collector of the transistor 526 increases, and a current flowing to the emitter of the transistor 516a is equal to the current I_{offset}. In this way, in the power amplification module 500, the current I_{offset} is controlled in accordance with the base potential of the differential pair of transistors 541 and 542. In this case, since the current I_{offset} is not controlled in accordance with the collector potential of the transistor 426, it is possible to suppress an increase in diffusion capacitance between the base and the collector of the transistor 426 and to prevent a delay in a case where the collector potential of the transistor 426 is raised. Therefore, the response speed of the limiter circuit 540 is increased.

In addition, in the above description, the base potential of the transistor 541 and the base potential of the transistor 542 are described as being equal to each other, but the present disclosure is not limited to this. For example, in the power amplification module 500, by adjusting the resistance value of the resistor 545 and the bias condition of the transistor 527, a current flowing to the transistor 516a in a case where the peak amplifier 515 does not operate can be adjusted.

In addition, in the above description, the emitter of the transistor 541 may be electrically connected to the emitter of the transistor 542 through a resistor. Accordingly, the response speed of the limiter circuit 540 can be adjusted.

### Sixth Modification Example

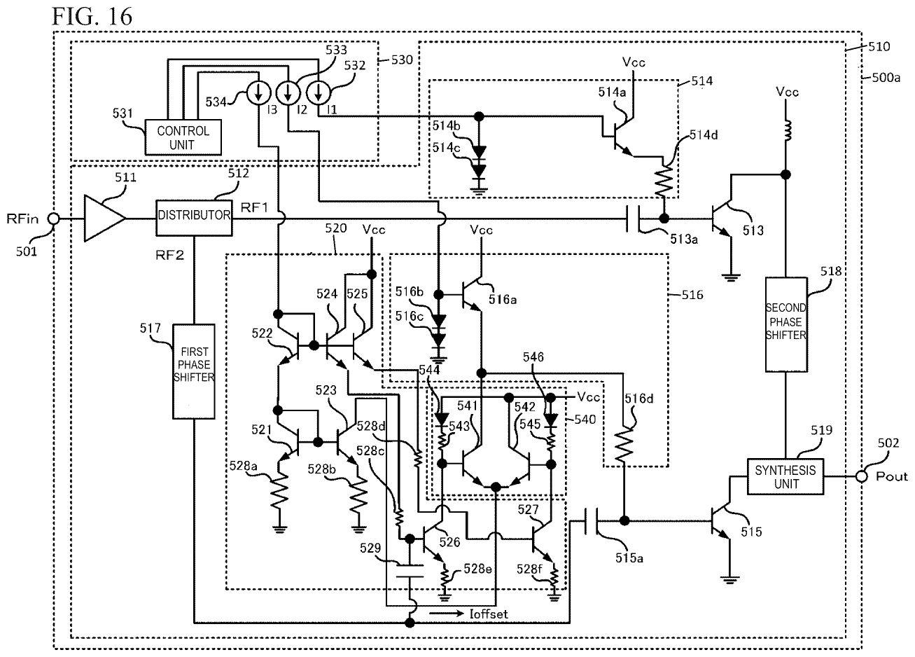

Next, a power amplification module 500a according to a sixth modification example will be described with reference to FIG. 16. FIG. 16 is a diagram showing an example of the configuration of the power amplification module 500a according to the sixth modification example. In the sixth modification example, descriptions of the common matters with those of the power amplification module 500 shown in FIG. 15 will be omitted, and only differences will be described. In particular, the same operation and effects resulting from the same configuration will not be sequentially referred to.

The power amplification module 500a is configured such that the collector of the transistor 541 is electrically connected to the emitter of the transistor 516a, and the power supply voltage Vcc is supplied to the collector of the transistor 542, compared to the power amplification module 500.

In the power amplification module 500a, as the input signal RF2 increases, the current flowing to the transistor 516a decreases and finally does not flow. That is, the power amplification module 500a has a configuration effective in a case where the peak amplifier 515 can sufficiently largely secure the bias current by the self-bias effect.

### Summary

A power amplification module 100 according to an exemplary embodiment of the present disclosure includes a carrier amplifier 113, a carrier bias circuit 114 that supplies a bias to the carrier amplifier 113, a peak amplifier 115, and a peak bias circuit 116 that includes a transistor 116a (first transistor) having a collector or a drain connected to a reference potential and that supplies a bias to the peak amplifier 115 from an emitter or a source of the transistor 116a (first transistor), and the peak bias circuit 116 is electrically connected to a current output circuit 120 that outputs a predetermined current from the emitter or the source of the transistor 116a (first transistor). Accordingly, the power amplification module 100 improves the delay in the response of the bias circuit in the peak amplifier.

In addition, the power amplification module 100 according to the exemplary embodiment of the present disclosure further includes the current output circuit 120. Accordingly, the power amplification module 100 improves the delay in the response of the bias circuit in the peak amplifier.

In addition, the current output circuit 120 of the power amplification module 100 according to the exemplary embodiment of the present disclosure includes a transistor 121 (second transistor) that has a collector or a drain supplied with a reference current I₃ (first current) from the current control circuit 130 and an emitter or a source electrically connected to the reference potential and that is diode-connected, and a transistor 122 (third transistor) having a base or a gate electrically connected to a base or a gate of the transistor 121 (second transistor), a collector or a drain electrically connected to the emitter or the source of the transistor 116a (first transistor) and an emitter or a source electrically connected to the reference potential. Accordingly, in the power amplification module 100, since the output impedance of the peak bias circuit 116 can be reduced before the peak amplifier 115 performs an amplification operation, it is possible to prevent the delay in the response of the peak bias circuit 116.

In addition, the transistor 121 (second transistor) of the power amplification module 100 according to the exemplary embodiment of the present disclosure has an emitter or a source electrically connected to the reference potential through a resistor 123 (first resistor), and the transistor 122 (third transistor) has an emitter or a source electrically connected to the reference potential through a resistor 124 (second resistor). Accordingly, in the power amplification module 100, since the output impedance of the peak bias circuit 116 can be reduced before the peak amplifier 115 performs an amplification operation, it is possible to prevent the delay in the response of the peak bias circuit 116.

In addition, an emitter or a source of a transistor 216a (first transistor) of a power amplification module 200 according to an exemplary embodiment of the present disclosure is electrically connected to a node 215b through a resistor 216d (third resistor), the node 215b being electrically connected to an input terminal of the peak amplifier 215, and a collector or a drain of a transistor 222 (third transistor) of the current output circuit 220 is electrically connected to the node 215b through a resistor 225 (fourth resistor). Accordingly, in the power amplification module 200, since the deep Class C bias can be applied to each of a plurality of the peak amplifiers 215, the peak amplifier can be operated only in a case where the input signal is large. Therefore, the power consumption can be reduced.

In addition, the carrier bias circuit 114 of a power amplification module 100a according to an exemplary embodiment of the present disclosure includes a transistor 114a (fourth transistor) having a collector or a drain connected to the reference potential, and in the current output circuit 120a, a collector or a drain of a transistor 114c (second transistor) is supplied with a reference current I₁ (first current) from the current control circuit 130 through a diode-connected transistor 114b (fifth transistor), and a base or a gate of a transistor 114a (fourth transistor) is electrically connected to a base or a gate of the transistor 114b (fifth transistor). Accordingly, the power amplification module 100a can be configured with a small circuit.

In addition, the carrier bias circuit 114 of a power amplification module 100b according to an exemplary embodiment of the present disclosure includes a transistor 114a (fourth transistor) having a collector or a drain connected to the reference potential, and a base or a gate supplied with a reference current I₂ (second current) different from the reference current I₁ (first current) from the current control circuit 130, and in the current output circuit 120, a base or a gate of the transistor 116a (first transistor) is electrically connected to the base or the gate of the transistor 114a (fourth transistor). Accordingly, the power amplification module 100b can be configured with a small circuit.

In addition, the carrier bias circuit 114 of a power amplification module 100c according to an exemplary embodiment of the present disclosure includes a transistor 114a (fourth transistor) having a collector or a drain connected to the reference potential and a base or a gate supplied with the reference current I₁ (first current) from the current control circuit 130, the base or the gate of the transistor 114a (fourth transistor) is electrically connected to a base or a gate of the transistor 116a (first transistor), and the current output circuit 120 further includes a transistor 121c (fifth transistor) that has an emitter or a source electrically connected to a collector or a drain of a transistor 122c (second transistor), a collector or a drain supplied with the reference current I₁ (first current) from the current control circuit 130, and a base or a gate electrically connected to the base or the gate of the transistor 114a (fourth transistor) and the base or the gate of the transistor 116a (first transistor) and that is diode-connected. Accordingly, in the power amplification module 100c, even in a case where the peak amplifier 115 does not perform an amplification operation, a current can be caused to flow to the emitter of the transistor 116a. Therefore, it is possible to reduce the output impedance of the peak bias circuit 116 in a case where the peak amplifier 115 starts to operate.

In addition, a current output circuit 320 of a power amplification module 300 according to an exemplary embodiment of the present disclosure is a resistor 320a (resistance element) having one end electrically connected to an emitter or a source of a transistor 316a (first transistor) and the other end connected to the reference potential. Accordingly, the power amplification module 300 can cause a current to always flow to the transistor 316a of the peak bias circuit 316 by a small number of elements.

In addition, a peak amplifier 315 of the power amplification module 300 according to the exemplary embodiment of the present disclosure includes a transistor 315 (sixth transistor) having an emitter or a source connected to the reference potential, and the other end of the resistor 320a (resistance element) of the current output circuit 320 is electrically connected to the emitter or the source of the transistor 315 (sixth transistor). Accordingly, wiring for connecting each of the resistors 320a to the ground is facilitated.

In addition, a peak amplifier 415 of a power amplification module 400 according to an exemplary embodiment of the present disclosure includes a transistor 415 (sixth transistor) having a base or a gate to which an input signal is input through a capacitor 415a (first capacitor), the current output circuit 420 includes a transistor 421 (seventh transistor) having a collector or a drain connected to the reference potential and a base or a gate supplied with a current from a current control circuit 430, and a transistor 426 (eighth transistor) having a base or a gate electrically connected to an emitter or a source of the transistor 421 (seventh transistor) through a resistor 425 (fifth resistor) and a collector or a drain electrically connected to an emitter or a source of a transistor 416a (first transistor), and the base or the gate of the transistor 426 (eighth transistor) is electrically connected to the base or the gate of the transistor 415 (sixth transistor) such that the input signal is input through a capacitor 428 (second capacitor). Accordingly, in the power amplification module 400, since the current I_{SB} is increased in a case where the power level of the input signal RF2 is increased, it is possible to suppress the operation of the peak amplifier 415 in the low input signal RF2.

In addition, the power amplification module 400 according to the exemplary embodiment of the present disclosure further includes a limiter circuit 440 that is electrically connected in series between the emitter or the source of the transistor 416a (first transistor) and the collector or the drain of the transistor 426 (eighth transistor) and limits a current flowing to the collector or the drain of the transistor 426 (eighth transistor). Accordingly, since the power amplification module 400 can suppress an increase in current flowing to the collector of the transistor 442, the operation of the peak amplifier 415 can be appropriately controlled even in a case where the input signal RF2 is increased.

In addition, the carrier bias circuit 414 of a power amplification module 400b according to an exemplary embodiment of the present disclosure includes a transistor 414a (fourth transistor) having a base or a gate supplied with a current from the current control circuit 430, and the transistor 421 (seventh transistor) has a base or a gate electrically connected to the base or the gate of the transistor 414a (fourth transistor). Accordingly, in the power amplification module 400b, since the number of diodes can be reduced, and the third output terminal 433 for supplying the reference current I₃ to the current output circuit 420 is unnecessary, the size of the circuit can be reduced.

In addition, a limiter circuit 440 of the power amplification module 400 according to the exemplary embodiment of the present disclosure includes a transistor 442 (ninth transistor) having a base or a gate electrically to a reference voltage circuit 441 (voltage setting circuit) for setting a reference voltage and an emitter or a source electrically connected to the collector or the drain of the transistor 426 (eighth transistor) through a resistor 443 (sixth resistor). Accordingly, since the power amplification module 400 can suppress an increase in current flowing to the collector of the transistor 442, the operation of the peak amplifier 415 can be appropriately controlled even in a case where the input signal RF2 is increased.

In addition, the limiter circuit 440 of the power amplification module 400 according to the exemplary embodiment of the present disclosure includes a transistor 442 (ninth transistor) having a base or a gate electrically connected to a reference voltage circuit 441 (voltage setting circuit) for setting a reference voltage and an emitter or a source electrically connected to the collector or the drain of the transistor 426 (eighth transistor) through a resistor 443 (sixth resistor). Accordingly, since the power amplification module 400 can suppress an increase in current flowing to the collector of the transistor 442, the operation of the peak amplifier 415 can be appropriately controlled even in a case where the input signal RF2 is increased.

In addition, a power amplification module 500 according to an exemplary embodiment of the present disclosure further includes a limiter circuit 540 including a transistor 541 (tenth transistor) having a collector or a drain supplied with a power supply voltage and the collector or the drain and a base or a gate electrically connected through a resistor 543 (seventh resistor), and a transistor 542 (eleventh transistor) having a collector or a drain electrically connected to an emitter or a source of a transistor 516a (first transistor) and a base or a gate supplied with the power supply voltage through a resistor 545 (eighth resistor), and an emitter or a source electrically connected to an emitter or a source of the transistor 541 (tenth transistor), the current output circuit 520 includes a transistor 526 (twelfth transistor) having a base or a gate supplied with a reference current I₃ from the current control circuit 530 and electrically connected to a base or a gate of a transistor 515 (sixth transistor) such that an input signal RF2 is input through a capacitor 529 (second capacitor), a collector or a drain electrically connected to a base or a gate of the transistor 541 (tenth transistor), and an emitter or a source electrically connected to the reference potential, and a transistor 527 (thirteenth transistor) having a base or a gate supplied with the reference current I₃ from the current control circuit 530, a collector or a drain electrically connected to a base or a gate of the transistor 542 (eleventh transistor), and an emitter or a source electrically connected to the reference potential, and the transistor 523 (third transistor) has a collector or a drain electrically connected to an emitter or a source of the transistor 542 (eleventh transistor). Accordingly, in the power amplification module 500, since the current I_{offset} is controlled in accordance with the base potential of the differential pair transistors 541 and 542, the response speed of the limiter circuit 540 is increased.

In addition, a power amplification module 500a according to an exemplary embodiment of the present disclosure further includes a limiter circuit 540 including a transistor 541 (tenth transistor) having a collector or a drain electrically connected to an emitter or a source of a transistor 516a (first transistor), a base or a gate supplied with a power supply voltage through a resistor 545 (seventh resistor), and a transistor 542 (eleventh transistor) having a collector or a drain supplied with the power supply voltage and the collector or the drain and a base or a gate electrically connected through a resistor 543 (eighth resistor), and an emitter or a source electrically connected to an emitter or a source of the transistor 541 (tenth transistor), the current output circuit 520 includes a transistor 526 (twelfth transistor) having a base or a gate supplied with a reference current I₃ from the current control circuit 530 and electrically connected to a base or a gate of a transistor 515 (sixth transistor) such that an input signal is input through a capacitor 529 (second capacitor), a collector or a drain electrically connected to a base or a gate of the transistor 541 (tenth transistor), and an emitter or a source electrically connected to the reference potential, and a transistor 527 (thirteenth transistor) having a base or a gate supplied with the reference current I₃ from the current control circuit 530, a collector or a drain electrically connected to a base or a gate of the transistor 542 (eleventh transistor), and an emitter or a source electrically connected to the reference potential, and the transistor 523 (third transistor) has a collector or a drain electrically connected to the emitter or the source of the transistor 541 (tenth transistor). Accordingly, the power amplification module 500a has a configuration effective in a case where the peak amplifier 515 can sufficiently largely secure the bias current by the self-bias effect.

The embodiments described above are intended to facilitate the understanding of the present disclosure and not to be construed as limiting the present disclosure. The present disclosure can be modified or improved without necessarily departing from the spirit of the present disclosure, and the present disclosure also includes equivalents thereof. That is, even configurations in which a person skilled in the art appropriately makes design changes to the embodiments are included in the scope of the present disclosure as long as the configurations have the features of the present disclosure. The elements provided in the embodiments, the arrangement thereof, and the like are not limited to those exemplified, and can be appropriately modified.

### REFERENCE SIGNS LIST

100, 100a, 100b, 100c, 200, 300, 400, 400a, 500 POWER AMPLIFICATION MODULE
110, 210, 310, 410, 510 POWER AMPLIFIER CIRCUIT
111 DRIVE STAGE AMPLIFIER CIRCUIT
112 DISTRIBUTOR
113 CARRIER AMPLIFIER
114 CARRIER BIAS CIRCUIT
115 PEAK AMPLIFIER
116 PEAK BIAS CIRCUIT
117 FIRST PHASE SHIFTER
118 SECOND PHASE SHIFTER
119 SYNTHESIS UNIT
120, 220, 320, 420, 520 CURRENT OUTPUT CIRCUIT
130, 230, 330, 430, 530 CURRENT CONTROL CIRCUIT
440, 540 LIMITER CIRCUIT

1. A power amplification module comprising:
a carrier amplifier circuit;
a carrier bias circuit configured to supply a bias to the carrier amplifier circuit;
a peak amplifier circuit; and
a peak bias circuit comprising a first transistor having a collector or a drain connected to a reference potential and that is configured to supply a bias to the peak amplifier circuit from an emitter or a source of the first transistor,
wherein the peak bias circuit is electrically connected to a current output circuit configured to output a predetermined current from the emitter or the source of the first transistor.

2. The power amplification module according to claim 1, further comprising:
the current output circuit.

3. The power amplification module according to claim 2, wherein the current output circuit comprises:
a diode-connected second transistor that has a collector or a drain supplied with a first current from a current control circuit and an emitter or a source electrically connected to the reference potential, and
a third transistor having a base or a gate electrically connected to a base or a gate of the second transistor, a collector or a drain electrically connected to the emitter or the source of the first transistor, and an emitter or a source electrically connected to the reference potential.

4. The power amplification module according to claim 3,
wherein the emitter or the source of the second transistor is electrically connected to the reference potential through a first resistor, and
wherein the emitter or the source of the third transistor is electrically connected to the reference potential through a second resistor.

5. The power amplification module according to claim 3,
wherein the emitter or the source of the first transistor is electrically connected to a node through a third resistor, the node being electrically connected to an input terminal of the peak amplifier circuit, and the collector or the drain of the third transistor being electrically connected to the node through a fourth resistor.

6. The power amplification module according to claim 3,
wherein the carrier bias circuit comprises a fourth transistor that has a collector or a drain supplied with a power supply voltage and that is configured to supply a bias to the carrier amplifier circuit from an emitter or a source,
wherein the collector or the drain of the second transistor is supplied with the first current from the current control circuit through a diode-connected fifth transistor, and
wherein a base or a gate of the fourth transistor is electrically connected to a base or a gate of the fifth transistor.

7. The power amplification module according to claim 3,
wherein the carrier bias circuit comprises a fourth transistor that has a collector or a drain supplied with a power supply voltage and that is configured to supply a bias to the carrier amplifier circuit from an emitter or a source, and a base or a gate supplied with a second current different from the first current from the current control circuit, and
wherein a base or a gate of the first transistor is electrically connected to the base or the gate of the fourth transistor.

8. The power amplification module according to claim 3,
wherein the carrier bias circuit comprises a fourth transistor that has a collector or a drain supplied with a power supply voltage and that is configured to supply a bias to the carrier amplifier circuit from an emitter or a source, and a base or a gate supplied with the first current from the current control circuit,
wherein the base or the gate of the fourth transistor is electrically connected to a base or a gate of the first transistor, and
wherein the current output circuit further comprises a diode-connected fifth transistor that has an emitter or a source electrically connected to a collector or a drain of the second transistor, a collector or a drain supplied with the first current from the current control circuit, and a base or a gate electrically connected to the base or the gate of the fourth transistor and the base or the gate of the first transistor.

9. The power amplification module according to claim 2, wherein the current output circuit is a resistance circuit element having a first end electrically connected to the emitter or the source of the first transistor and a second end connected to the reference potential.

10. The power amplification module according to claim 9,
wherein the peak amplifier circuit comprises a sixth transistor having an emitter or a source connected to the reference potential, and
wherein the second end of the resistance circuit element of the current output circuit is electrically connected to the emitter or the source of the sixth transistor.

11. The power amplification module according to claim 2,
wherein the peak amplifier circuit comprises a sixth transistor having a base or a gate to which an input signal is input through a first capacitor,
wherein the current output circuit comprises:
a seventh transistor having a collector or a drain supplied with a power supply voltage, and a base or a gate supplied with a current from a current control circuit,
an eighth transistor having a base or a gate electrically connected to an emitter or a source of the seventh transistor through a fifth resistor, and a collector or a drain electrically connected to the emitter or the source of the first transistor, and
wherein the base or the gate of the eighth transistor is electrically connected to the base or the gate of the sixth transistor such that the input signal is input through a second capacitor.

12. The power amplification module according to claim 11, further comprising:
a limiter circuit that is electrically connected in series between the emitter or the source of the first transistor and the collector or the drain of the eighth transistor, and that is configured to limit a current flowing to the collector or the drain of the eighth transistor.

13. The power amplification module according to claim 12,
wherein the carrier bias circuit comprises a fourth transistor having a base or a gate supplied with a current from the current control circuit, and that is configured to supply a bias to the carrier amplifier circuit from an emitter or a source of the fourth transistor, and
wherein the seventh transistor has a base or a gate electrically connected to the base or the gate of the fourth transistor.

14. The power amplification module according to claim 12,
wherein the limiter circuit comprises a ninth transistor having a base or a gate electrically connected to a voltage setting circuit configured to set a reference voltage, and an emitter or a source electrically connected to the collector or the drain of the eighth transistor through a sixth resistor.

15. The power amplification module according to claim 12,
wherein the limiter circuit comprises a ninth transistor having a base or a gate electrically connected to a voltage setting circuit configured to set a reference voltage through a sixth resistor, and an emitter or a source electrically connected to the collector or the drain of the eighth transistor.

16. The power amplification module according to claim 3, further comprising:
a limiter circuit comprising:
a tenth transistor having a collector or a drain supplied with a power supply voltage and the collector or the drain, and a base or a gate electrically connected through a seventh resistor, and
an eleventh transistor having a collector or a drain electrically connected to the emitter or the source of the first transistor, a base or a gate supplied with the power supply voltage through an eighth resistor, and an emitter or a source electrically connected to an emitter or a source of the tenth transistor,
wherein the current output circuit comprises:
a twelfth transistor having a base or a gate supplied with a reference current from the current control circuit and that is electrically connected to a base or a gate of a transistor of the peak amplifier circuit, a collector or a drain electrically connected to the base or the gate of the tenth transistor, and an emitter or a source electrically connected to the reference potential, and
a thirteenth transistor having a base or a gate supplied with the reference current from the current control circuit, a collector or a drain electrically connected to the base or the gate of the eleventh transistor, and an emitter or a source electrically connected to the reference potential,
wherein the third transistor has a collector or a drain electrically connected to the emitter or the source of the tenth transistor and electrically connected to the emitter or the source of the eleventh transistor, and
wherein an input signal is input through a second capacitor.

17. The power amplification module according to claim 3, further comprising:
a limiter circuit comprising:
a tenth transistor having a collector or a drain electrically connected to the emitter or the source of the first transistor, a base or a gate supplied with a power supply voltage through a seventh resistor, and
an eleventh transistor having a collector or a drain supplied with the power supply voltage, the collector or the drain and a base or a gate electrically connected through an eighth resistor, and an emitter or a source electrically connected to an emitter or a source of the tenth transistor,
wherein the current output circuit comprises:
a twelfth transistor having a base or a gate supplied with a reference current from the current control circuit and electrically connected to a base or a gate of a transistor of the peak amplifier circuit, a collector or a drain electrically connected to the base or the gate of the tenth transistor, and an emitter or a source electrically connected to the reference potential, and
a thirteenth transistor having a base or a gate supplied with the reference current from the current control circuit, a collector or a drain electrically connected to the base or the gate of the eleventh transistor, and an emitter or a source electrically connected to the reference potential,
wherein the third transistor has a collector or a drain electrically connected to the emitter or the source of the tenth transistor and electrically connected to the emitter or the source of the eleventh transistor, and
wherein an input signal is input through a second capacitor.
